(19) United States
(12) Patent Application Publication
(10) Pub. No.: US 2025/0349714 A1
(43) Pub. Date: Nov. 13, 2025

(54) BACKSIDE INTERLAYER DIELECTRIC AIRGAP

(71) Applicant: INTERNATIONAL BUSINESS MACHINES CORPORATION, Armonk, NY (US)

(72) Inventors: Xiaoli He, Clifton Park, NY (US); Tao Li, Slingerlands, NY (US); Ruilong Xie, Niskayuna, NY (US); Nicolas Jean Loubet, Guilderland, NY (US)

(21) Appl. No.: 18/656,916

(22) Filed: May 7, 2024

(51) Int. Cl. H01L 23/528; H01L 29/06; H01L 29/423; H01L 29/775; H01L 29/786

(52) U.S. Cl. CPC H01L 23/5283; H10D 30/43; H10D 30/6735; H10D 30/6757; H10D 62/121

(57) ABSTRACT

A semiconductor device includes front end of line (FEOL) devices arranged in a FEOL layer defining a frontside and a backside opposite the frontside. A single composition dielectric material covers the FEOL devices and is disposed in shallow trench isolation regions between the FEOL devices. The dielectric material has voids disposed therein that provide airgaps between the FEOL devices.

### BACKGROUND

The present invention generally relates to semiconductor devices and processing methods, and more particularly to semiconductor devices with airgaps formed to reduce capacitance between components.

With backside processing of field effect transistors, capacitance between gate structures and middle of the line (MOL) contacts to source/drain regions can have a negative impact on device performance. While employing an ultra-low dielectric constant material to replace frontside interlayer dielectric can assist in reducing capacitance, it is often inadequate especially with shrinking node size. While airgaps can provide improvements in achieving ultra-low dielectric constant material, airgaps are difficult to integrate into process flows. Further, it is difficult to control a size and shape of airgaps.

Therefore, a need exists for reducing capacitance between gate structures and MOL contacts in devices with scaled down node sizes that is easy to integrate into a process flow and provides a repeatable result.

### SUMMARY

In accordance with an embodiment of the present invention, a semiconductor device includes front end of line (FEOL) devices arranged in a FEOL layer defining a frontside and a backside opposite the frontside. A single composition dielectric material covers the FEOL devices and is disposed in shallow trench isolation regions between the FEOL devices. The dielectric material has voids disposed therein that provide airgaps between the FEOL devices.

In other embodiments, the single composition dielectric material can fill the shallow trench isolation regions and can include a backside airgap within the shallow trench isolation regions. The backside airgap can extend under a gate conductor on the backside. The backside airgap can extend between backside contacts. The single composition dielectric material can line a region of a frontside interlayer dielectric and can include a frontside airgap within a region of the frontside interlayer dielectric. The frontside airgap can be disposed between middle of the line contacts. The frontside airgap can be disposed between source/drain regions of the FEOL devices. Backside power rails can connect to the FEOL devices by backside contacts. The backside power rails can include an extension that forms a portion of the backside contacts.

In accordance with another embodiment of the present invention, a semiconductor device includes front end of line (FEOL) devices arranged in a FEOL layer defining a frontside and a backside opposite the frontside. A single composition dielectric material covers the FEOL devices and is disposed in shallow trench isolation regions between the FEOL devices. The single composition dielectric has an airgap that extends from within the shallow trench isolation regions to a region of a frontside interlayer dielectric between the FEOL devices.

In other embodiments, the airgap can extend under a gate conductor on the backside. The airgap can extend between backside contacts. The airgap can be disposed between middle of the line contacts. The airgap can be disposed between source/drain regions of the FEOL devices. Backside power rails can connect to the FEOL devices by backside contacts. The backside power rails can include an extension that forms a portion of the backside contacts.

In accordance with another embodiment of the present invention, a semiconductor device includes front end of line (FEOL) devices arranged in a FEOL layer defining a frontside and a backside opposite the frontside. A single composition dielectric material covers the FEOL devices and disposed in shallow trench isolation regions between the FEOL devices. The single composition dielectric has an airgap that extends from within the shallow trench isolation regions to a region of a frontside interlayer dielectric between the FEOL devices. The single composition dielectric includes in a backside interlayer dielectric and disposed between backside contacts and buried power rails.

In other embodiments, the airgap can extend under a gate conductor and between the backside contacts on the backside. The airgap can be disposed between middle of the line contacts and between source/drain regions of the FEOL devices. The backside power rails can include an extension that forms a portion of the backside contacts.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows cross-sectional views, taken at section lines X, Y1 and Y2 as depicted in an inset (and referred to as sections X, Y1 and Y2, respectively), of a semiconductor device formed by processing one or more nanosheets and including source/drain regions formed as electrodes, in accordance with an embodiment of the present invention;

FIG. 2 shows cross-sectional views, taken at section lines X, Y1 and Y2, depicting removal of a semiconductor substrate, etch stop layer and semiconductor layer, in accordance with an embodiment of the present invention;

FIG. 3 shows cross-sectional views, taken at section lines X, Y1 and Y2, depicting a backside interlayer dielectric fill and planarization, in accordance with an embodiment of the present invention;

FIG. 4 shows cross-sectional views, taken at section lines X, Y1 and Y2, depicting sacrificial placeholder removal and backside contact formation, in accordance with an embodiment of the present invention;

FIG. 5 shows cross-sectional views, taken at section lines X, Y1 and Y2, depicting the backside contact recessed and a dielectric cap formed in the recess, in accordance with an embodiment of the present invention;

FIG. 6 shows cross-sectional views, taken at section lines X, Y1 and Y2, depicting shallow trench isolation dielectric and some of a frontside interlayer dielectric removed, in accordance with an embodiment of the present invention;

FIG. 7 shows cross-sectional views, taken at section lines X, Y1 and Y2, depicting shallow trench isolation dielectric and all of a frontside interlayer dielectric removed, in accordance with an embodiment of the present invention;

FIG. 8 shows cross-sectional views, taken at section lines X, Y1 and Y2, depicting a single composition dielectric material filling voids left by the shallow trench isolation dielectric and some of a frontside interlayer dielectric to form airgaps therein, in accordance with an embodiment of the present invention;

FIG. 9 shows cross-sectional views, taken at section lines X, Y1 and Y2, depicting a single composition dielectric material filling voids left by the shallow trench isolation dielectric and the frontside interlayer dielectric to form airgaps therein, in accordance with an embodiment of the present invention;

FIG. 10 shows cross-sectional views, taken at section lines X, Y1 and Y2, depicting backside power rails patterned in the single composition dielectric material, in accordance with an embodiment of the present invention;

FIG. 11 shows cross-sectional views, taken at section lines X, Y1 and Y2, depicting a dielectric cap removed and backside power rails formed including an extension that forms part of a backside contact, in accordance with an embodiment of the present invention; and

FIG. 12 shows cross-sectional views, taken at section lines X, Y1 and Y2, depicting a backside interconnect layer formed, in accordance with an embodiment of the present invention.

### DETAILED DESCRIPTION

In accordance with embodiments of the present invention, devices and methods are described which include airgaps formed from a backside of a semiconductor device. The airgaps can be disposed in backside regions and can be extended to frontside regions. With wafer backside processing, backside shallow trench isolation (STI) regions and frontside interlayer dielectric (ILD) can be leveraged to improve capacitance by removing dielectric material to form airgaps to further reduce dielectric constant (K) value. In an embodiment, a backside ILD and a frontside ILD can be partially or fully removed to form the airgaps. The removed dielectric is replaced with a single composition dielectric material. The single composition dielectric material is deposited in a non-conformal process to line cavities or voids left behind when shallow trench isolation regions, backside ILD and/or frontside ILD are removed. The single composition dielectric material refers to a replacement dielectric material that is applied in a single step and includes a same material composition throughout.

In an embodiment, a semiconductor device in accordance with the present embodiments includes airgaps formed around STI regions of front end of the line (FEOL) devices. In another embodiment, airgaps can be formed in STI regions of FEOL devices, and also in between middle of the line (MOL) contacts, and lower level back end of the line (BEOL) interconnects.

In an embodiment, a source/drain region of a field effect transistor (FET) can be connected to backside interconnect through a backside source/drain contact and backside power rail (BSPR). The backside source/drain contact can be partially recessed, and material of the BSPR can be employed to fill in the partially recessed region. The partially recessed region is surrounded by the backside ILD and an STI liner. Other FETs can have a source/drain region connected of a frontside to a BEOL layer through a MOL source/drain contact. The BSPR under the source/drain region of the other FETs does not extend into a recess of a backside contact.

The airgaps in accordance with present embodiments provide a decreased dielectric constant (K) to improve capacitance between conductive components, e.g., contacts, gate conductors, etc. In embodiments, removing some but not all dielectric materials to form airgaps can still provide some improvement. Remnants of dielectric materials can remain surrounding the airgaps.

In other embodiments, methods for fabricating a semiconductor device can include forming a backside ILD and planarizing the backside ILD, e.g., by chemical mechanical polishing (CMP). The backside ILD needs to be selectively removable relative to surrounding materials. For example, if oxide is employed for other surrounding materials, a material different than oxide should be employed for the backside ILD so that portions may be selectively removed by etching. Earlier formed sacrificial placeholders are removed from contact with source/drain regions, and backside contacts are formed. Selected backside contacts are recessed and a dielectric material is formed in the recess to form a cap. The cap is formed from a different dielectric to permit selective etching.

Selective removal of STI dielectric (e.g., oxide) and an open of a poly-open chemical mechanical polish (POC) liner (a nitride) can be followed by a FEOL ILD etch. A non-conformal backside ILD deposition (e.g., a single composition dielectric material) can be performed to form airgaps in the FEOL region. The airgaps can be above and/or below source/drain regions of the FEOL FETs.

In an embodiment, a method for forming a semiconductor device includes BEOL structure formation and carrier wafer bonding, after FEOL and MOL processing. A substrate can be removed from a backside of the semiconductor device. A backside ILD fill and a chemical mechanical polish (CMP) are performed. The backside ILD fill employs a dielectric that can be selectively removed relative to other materials. For example, if oxides are employed for the other materials than the backside ILD can include, e.g., nitride.

Sacrificial placeholders, which are formed for source/drain regions are removed to access the source/drain regions, and backside contacts are formed in place of the sacrificial placeholders. The backside contacts can be recessed, and a dielectric cap is formed in the recess. The dielectric cap includes a material that remains during an STI and/or ILD etch. The STI, POC open and ILD etch are performed selectively. A non-conformal backside ILD deposition (e.g., a single composition dielectric material) forms airgaps in the FEOL region. The airgaps can be above and/or below source/drain regions of the FEOL FETs. Backside power rails are deposited and patterned. The cap is selectively removed, and connections to the backside power rails are made. A backside interconnect layer is formed to make further connections on the backside of the semiconductor device.

In accordance with embodiments of the present invention, by removing material of the STI and the FILD, a void is formed where a single composition dielectric material can be deposited. The single composition dielectric material lines the walls of the void to concurrently form a liner with airgaps to provide a dielectric barrier between devices that reduces undesirable capacitances between components. By first creating a void and then forming a liner, a more repeatable process for integrating airgaps is achieved.

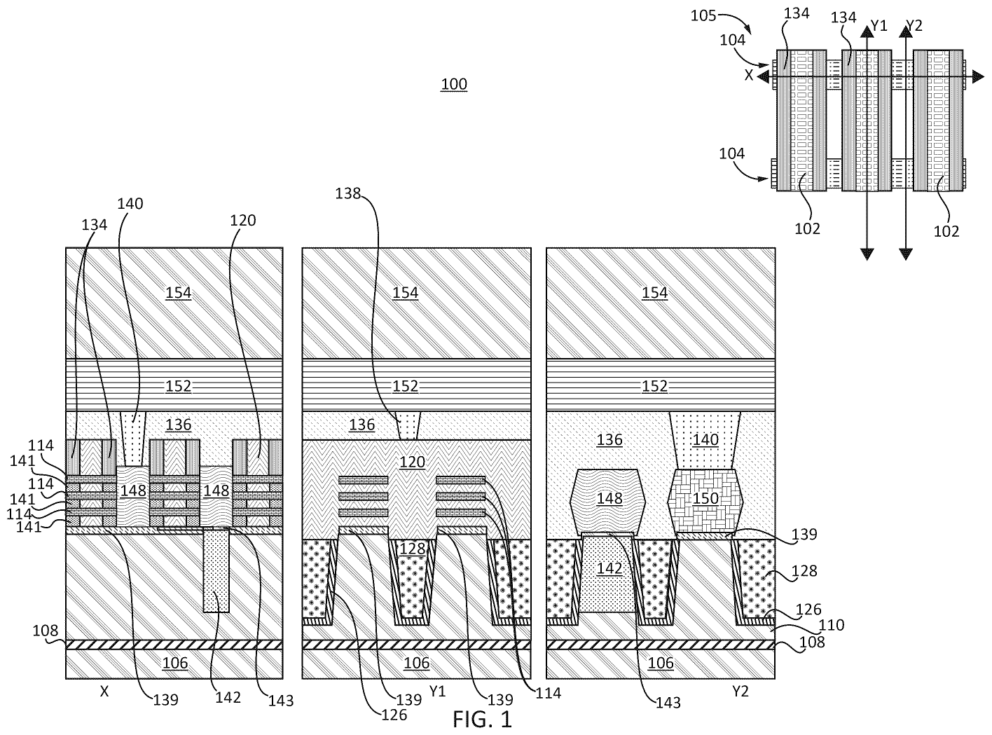

Referring now to the drawings in which like numerals represent the same or similar elements and initially to FIG. 1, devices and methods for manufacturing field effect transistor (FET) devices are shown in accordance with embodiments of the present invention. While illustrative embodiments will be described for nanosheet FETs, the present embodiments are not limited to nanosheet FETs. Other structures can also benefit in accordance with embodiments of the present invention, such as, e.g., finFETs or other structures.

A wafer 100 includes a substrate 106 having one or more layers on which FET devices are fabricated. FIG. 1 depicts three cross-sectional views, X, Y1 and Y2, taken at corresponding sections X, Y1 and Y2 in inset 105. Inset 105 shows gate lines 102 and active region lines 104 for reference. Corresponding X, Y1 and Y2 views are depicted throughout FIGS. 1-12. Active region lines 104 represent source/drain (S/D) regions for transistor devices, and gate lines 102 are represented for such transistor devices. Transistor channels are formed on the active region lines 104 below the gate lines 102.

The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 108 is formed on the substrate 106. The etch stop layer 108 can include an epitaxially grown crystal structure. The etch stop layer 108 includes a material that permits the selective etching and removal the substrate 106 in later steps. In an embodiment, the etch stop layer 108 can include SiGe although depending on the material of the substrate 106, other materials can be selected, e.g., SiGeC, SiC, etc.

A semiconductor layer 110 is epitaxially grown on the etch stop layer 108. The semiconductor layer 110 can include a same material as the substrate 106, although other semiconductor materials can be employed, e.g., SiGe, SiGeC, SiC, etc.

A bottom dielectric isolation (BDI) 139 can be formed on the semiconductor layer 110. BDI 139 can include a nitride, such as silicon nitride, although other dielectric materials can be employed.

One or more nanosheets (NS) are applied to the semiconductor layer 110. The nanosheet includes layers of alternating semiconductor material. In an embodiment, a nanosheet stack includes alternating layers of semiconductors. Each of the semiconductor layers are selectively removeable relative to neighboring semiconductor layers, e.g., by a selective etching process. In an embodiment, one semiconductor layer type can include, e.g., SiGe, where Ge is between 30-55 atomic % of the compound. The other semiconductor layer type can include, e.g., Si, which can form transistor channels 114 in the embodiment depicted. It should be understood that other materials or atomic percentages can be employed for these semiconductor layers. In other embodiments, different stack orders and numbers may be employed for the semiconductor layers in the nanosheet.

The nanosheet can be patterned to expose and etch the semiconductor layer 110. In an embodiment, a hard mask (not shown) may be formed by blanket depositing a layer of hard mask material, providing a patterned photoresist on top of the layer of hard mask material, and then etching the layer of hard mask material to provide the hard mask pattern for etching the nanosheet. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

Semiconductor layer 110 is further etched to form shallow trenches therein. Shallow trench isolation (STI) is formed in the etched trenches. In an embodiment, a dielectric liner 126 can be formed by depositing a conformal dielectric material, which can include, e.g., a SiN, or SiON, in the trenches. Then, the STI 128 is formed over the dielectric liner 126 using another dielectric material that is selectively etchable relative to the dielectric liner 126. For example, STI 128 can include, e.g., SiO₂, SiOₓN_{y}, SiCO or other suitable compounds. The dielectric liner 126 and the STI 128 can be deposited using chemical vapor deposition (CVD), although other deposition methods can be employed. The dielectric liner 126 and the STI 128 can then be etched, e.g., by RIE, to a level of the semiconductor layer 110.

Within the trenches recessed into the semiconductor layer 110, a sacrificial placeholder 142 can be formed. The sacrificial placeholder 142 can be epitaxially grown in the trenches of semiconductor layer 110 and a semiconductor material buffer layer 143 can be provided over the sacrificial placeholder 142. The sacrificial placeholder 142 can include SiGe or other epitaxial grown material that can be selectively removed relative to the semiconductor layer 110.

In some embodiments, a dummy gate material is first employed for dummy gates (not shown). The dummy gates are removed and a gate dielectric layer (not shown) is deposited to cover the transistor channels 114. The gate dielectric layer can be formed by, e.g., CVD or atomic layer deposition (ALD). Suitable examples of oxides that can be employed for the gate dielectric layer can include, but are not limited to: Al₂O₃, ZrO₂, HfO₂, Ta₂O₃, TiO₂ and combinations thereof.

A gate conductor 120 is formed over the gate dielectric layer and fills spaces between the transistor channels 114. This process is known as a High-K Metal Gate (HKMG) process to form gate structures for selectively activating FETs. The gate conductor 120 can include at least one gate conductor. The gate conductor 120 can include any conductive metal including, but not limited to W, Ni, Ti, Mo, Ta, Cu, Pt, Ag, Au, Ru, Ir, Rh, and Re, and alloys that include at least one of these conductive materials. The gate conductor 120 can include one or more layers of conductive materials. In one example, a second conductive material may be formed. When a combination of conductive elements is employed, an optional diffusion barrier material such as TaN or WN may be formed between the conductive materials. The gate conductor 120 can be deposited by CVD, plasma enhanced CVD (PECVD), ALD or other suitable deposition process.

A deposition process and a spacer etch are employed to form spacers 134. In an embodiment, the spacers 134 can be employed as an etch mask when patterning the nanosheet. Inner spacers 141 are formed and include a dielectric material. In an embodiment, the inner spacers 141 can be formed by recessing exposed portions of the now-removed semiconductor layer of the nanosheet. The portions of the semiconductor layer that are laterally recessed are filled with dielectric material to form the inner spacers 141.

An epitaxial growth process is performed to form source/drain regions 148 and 150. Source/drain regions 148, 150 can include, e.g., SiGe or Si and include faceted surfaces when epitaxial growth is not confined. The source/drain regions 148, 150 are epitaxially grown using material of the transistor channels 114 as a starting structure. The source/drain regions 148, 150 can be designated as P-type or N-type devices. For N-type devices, source/drain regions 148, 150 can include Si. For P-type devices, the source/drain regions 148, 150 can include SiGe.

The source/drain regions 148, 150 can be appropriately doped during their formation by epitaxial growth. For example, the source/drain regions 148, 150 can be doped by introducing P dopants (e.g., B, Ga, etc.) during epitaxial formation. Similarly, the source/drain regions 148 can be doped by introducing N dopants (e.g., P, As, etc.) during epitaxial formation. In other embodiments, P-type and N-type devices can be formed adjacent to one another. Processing would include forming one device type and then the other device type by employing block masks to protect each device during the processing of the other. Source/drain regions 148, 150 form part of front end of the line (FEOL) structures along with gate structures. The FEOL structure forms a layer across the wafer 100 which can delineate between a frontside or top and a backside or bottom of the wafer 100.

A frontside interlayer dielectric (FILD 136) is formed on the wafer 100. The FILD 136 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The FILD 136 can be deposited using CVD, although other deposition methods can be employed.

After formation of the FILD 136, a planarization process can be performed to planarize a top surface of the wafer 100. In an embodiment, the planarization process can include a chemical mechanical polish (CMP).

Middle of the line (MOL) contacts 138, 140 are formed to make connections to the gate conductor 120 and the source/drain regions 148, 150, respectively, from the top or frontside of the wafer 100. Trenches or holes are formed in the FILD 136. The trenches or holes expose the underlying conductive materials.

In some embodiments, a silicide liner, such as, e.g., Ti, Ni, NiPt is deposited first in contact with source/drain regions 148, 150 before formation of the MOL contacts 140, then a diffusion barrier can be formed in the trenches prior to a conductive fill. The diffusion barrier can include, e.g., TiN, TaN, or similar materials. For the MOL contacts 138, a diffusion barrier can be formed in the trenches prior to a conductive fill.

The conductive fill for forming the MOL contacts 138, 140 is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the MOL contacts 138, 140. The MOL contacts 138 are formed to make connections to the gate conductor 120 and the MOL contacts 140 make connections to the source/drain regions 148, 150 from the top or frontside of the wafer 100.

Processing continues with the formation of back end of the line (BEOL) structures in a BEOL layer 152, which can include metal structures and dielectric layers to complete the top side of a semiconductor device being fabricated. The BEOL layer 152 includes metal lines and vias and provides electrical access to FETs formed in the FEOL region through MOL contacts 138, 140. A carrier wafer 154 can be bonded to the BEOL layer 152 by employing a bonding oxide or other adhesive. The carrier wafer 154 provides support and transportability to the wafer 100 for further processing which includes flipping the wafer 100 and removing portions of a bottom or backside.

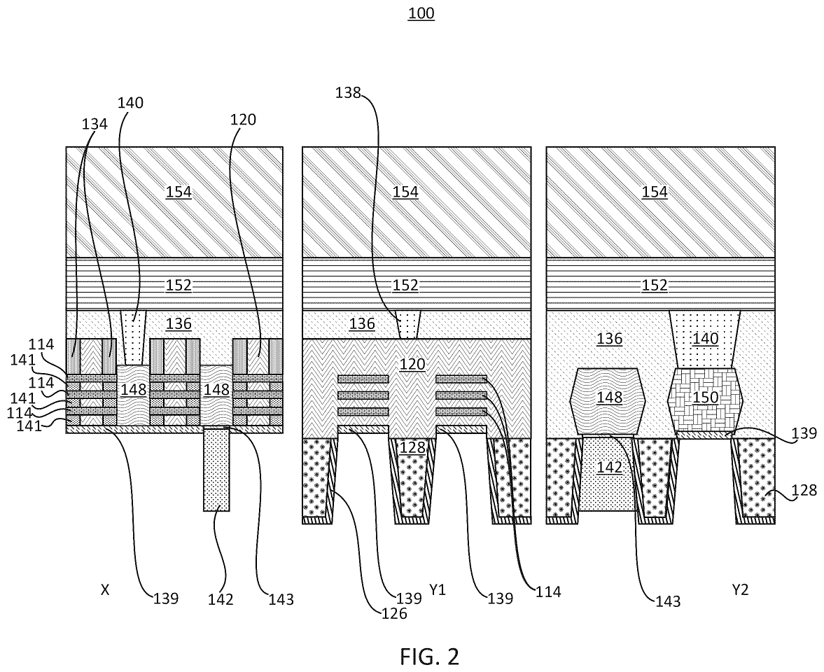

Referring to FIG. 2, to continue processing, the wafer 100 can be flipped to process features on the bottom side of the FET device. However, for clarity and consistency, the FET device will be shown in the FIGS. in a same orientation as previously described with continued and consistent reference to bottom/top. The substrate 106 is removed from the bottom side of the wafer 100. The substrate 106 can be removed by an etch process that stops on the etch stop layer 108. The etch stop layer 108 is then removed by an etch process. In an alternate embodiment, a CMP process can be employed to remove the substrate 106 and the etch stop layer 108. With the removal of the etch stop layer 108, the semiconductor layer 110 is exposed. The semiconductor layer 110 is removed by an etch process that selectively removes the material of the semiconductor layer 110 relative to the dielectric liner 126 and BDI 139.

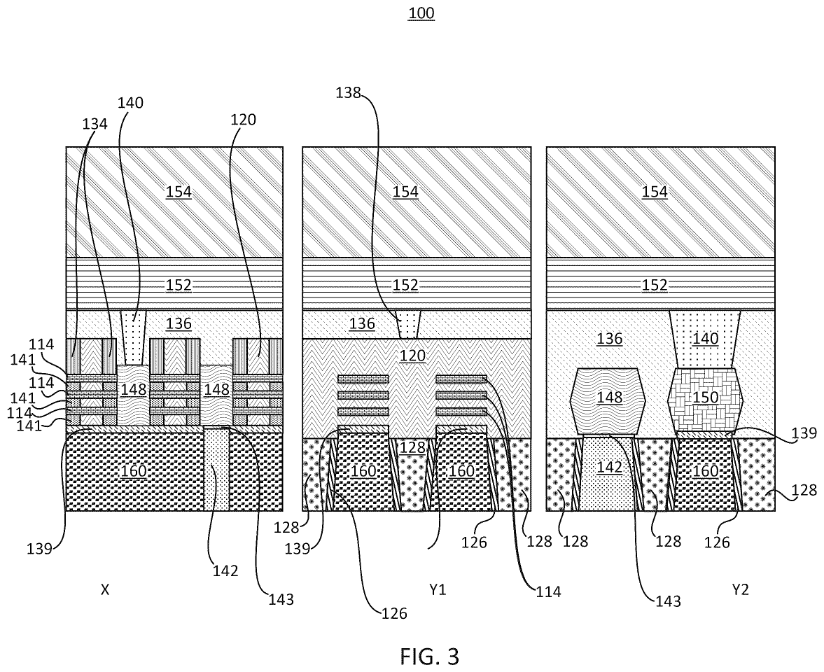

Referring to FIG. 3, a backside interlayer dielectric (BILD 160) is formed over the dielectric liner 126 and BDI 139. The BILD 160 includes a material that is selectively removeable relative to the dielectric liner 126 and BDI 139. The same process used for the formation of FILD 136 can be employed for BILD 160, although BILD 160 may include a different composition.

BILD 160 can include any suitable material depending on the materials selected for the FILD 136, the dielectric liner 126 and BDI 139, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H).

The BILD 160 can be deposited using CVD, although other deposition methods can be employed. The BILD 160 needs to be selectively etchable relative to the FILD 136. For example, if the FILD 136 is an oxide, the BILD 160 can be a nitride or oxynitride. After formation of the BILD 160, a planarization process can be performed to planarize a top surface of the wafer 100. In one embodiment, the planarization process can include a CMP.

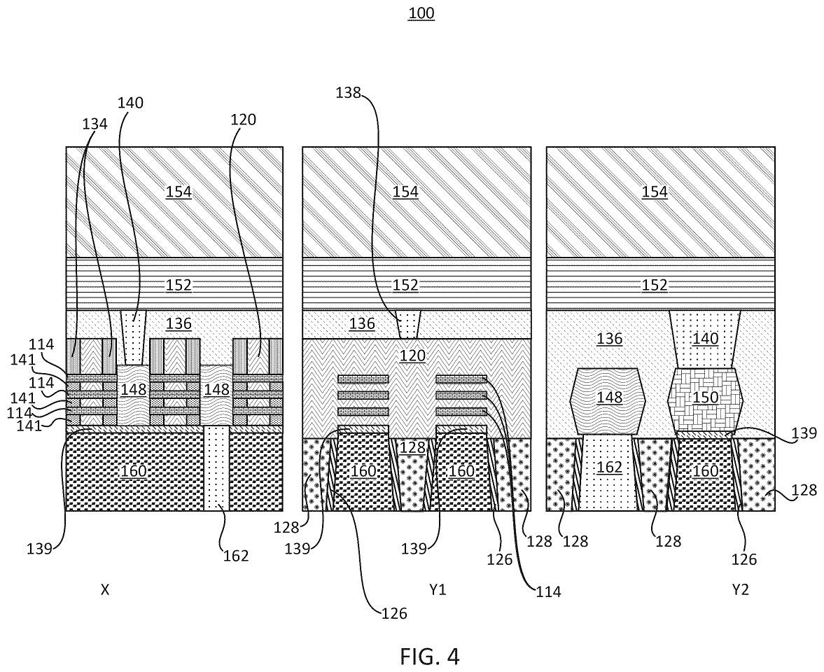

Referring to FIG. 4, the sacrificial placeholders 142 (FIG. 3) are removed by a selective wet or dry etch. Backside contacts 162 are formed to make connections with the source/drain regions 148 associated with the sacrificial placeholder 142 that has been removed. Openings formed by removing the sacrificial placeholder 142 are filled with conductive material.

A silicide liner (not shown), such as Ti, Ni, NiPt can be deposited in the openings formed by removing the sacrificial placeholder 142, then a diffusion barrier (not shown) can be formed in the opening prior to a conductive fill. The diffusion barrier can include, e.g., TiN, TaN, or similar materials. A conductive fill is performed to fill the opening. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form backside contacts 162.

In an embodiment, one opening is opened up per FET on a backside of the FET device such that only one electrode (source or drain) is contacted at the backside of the FET (e.g., backside contact 162) and only one electrode (drain or source) is contacted by at the frontside of the FET (e.g., MOL contacts 140). In this way, contact density is reduced on the frontside and the backside of the FET. This reduces or eliminates the possibility of shorts or opens that would otherwise be experienced in high metal density areas especially with devices with reduced node size.

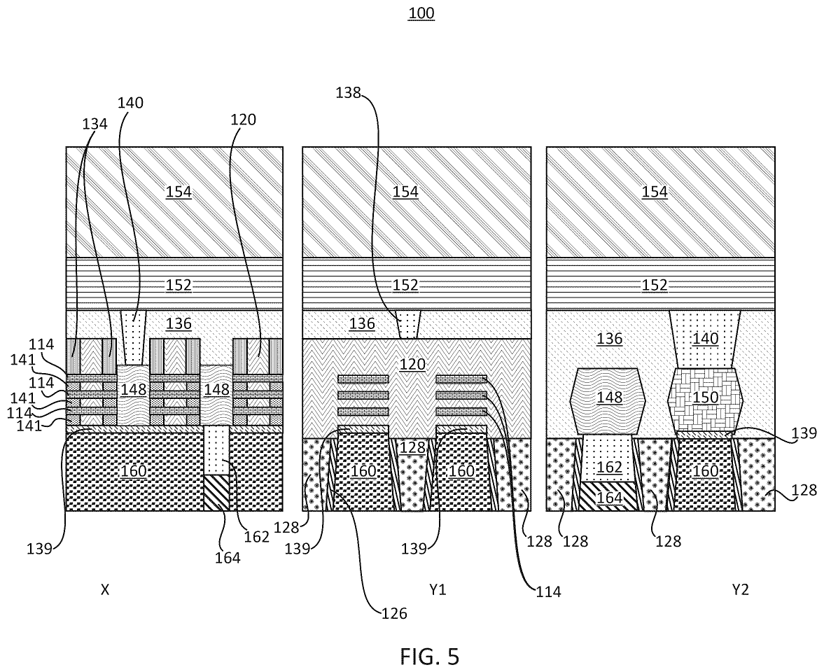

Referring to FIG. 5, the backside contacts 162 are recessed by being subjected to a timed selective etch. The etch selectively removes material of the backside contacts 162 relative to the BILD 160 and the dielectric liner 126. Once the backside contact 162 is recessed a dielectric material is deposited in the recess and the dielectric material is planarized (e.g., by CMP) to form a dielectric cap 164. The dielectric cap 164 includes a material that is resistant to etch processes consistent with the formation of airgaps in the BILD 160 and/or the FILD 136 in later steps. For example, if the FILD 136 is oxide, the dielectric cap 164 can include a nitride or oxynitride.

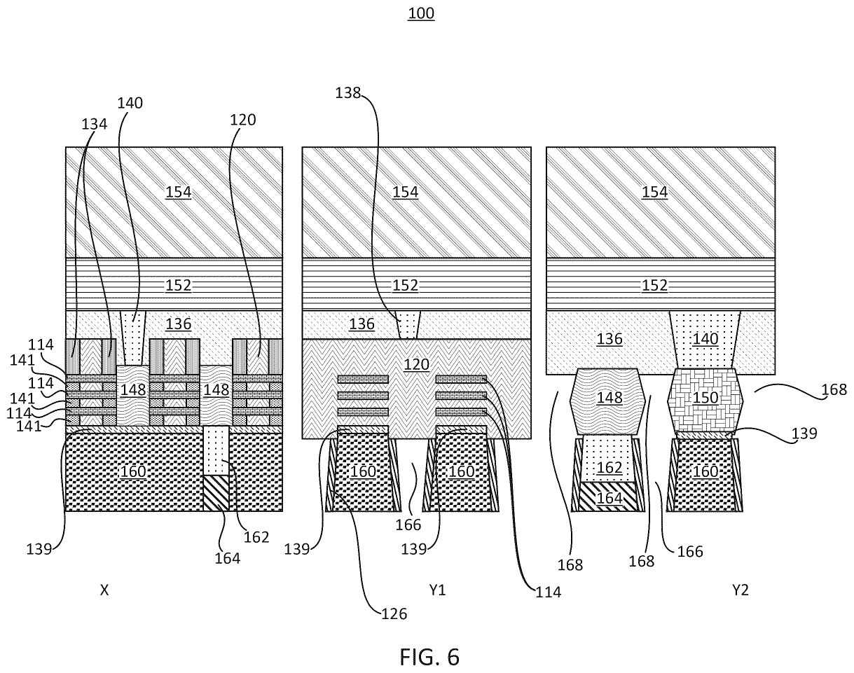

Referring to FIG. 6, some or all of the dielectric materials for STI 128 and further some or all of the FILD 136 can be removed. In an embodiment, an isotropic wet etch can be performed to remove some or all of the dielectric material for the STI 128 leaving voids 166. The etch can include a selective etch that selectively removes the material of the STI 128 relative to the dielectric liner 126 and the BILD 160. The etch can continue to remove some or all of the dielectric material for FILD 136 relative to the dielectric liner 126, the BILD 160 and the source/drain regions 148 and 150 (or the thin POC liner (not shown), if present, on the source/drain regions or other structures) to leave voids 168. In an embodiment, the removal of the STI 128 and/or the FILD 136 can stop at this stage. In other embodiments, etching can continue as will be described.

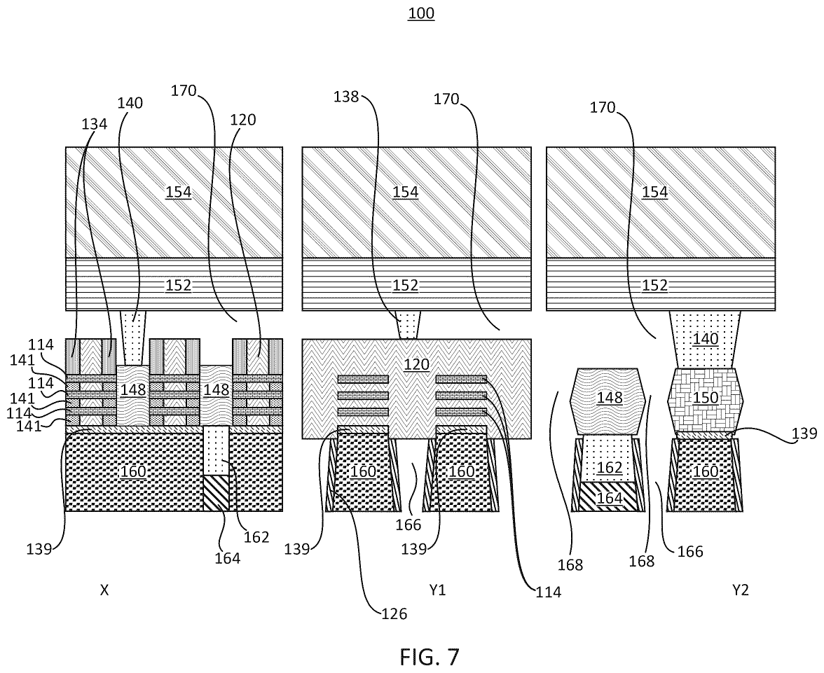

Referring to FIG. 7, the wet etch can continue to remove all of the dielectric material for FILD 136 relative to the dielectric liner 126, the BILD 160, the gate conductor 120, the spacers 134, the MOL contacts 138, 140, the source/drain regions 148 and 150 and the BEOL layer 152. The removal of FILD 136 leaves a void 170 in a space once occupied by the FILD 136.

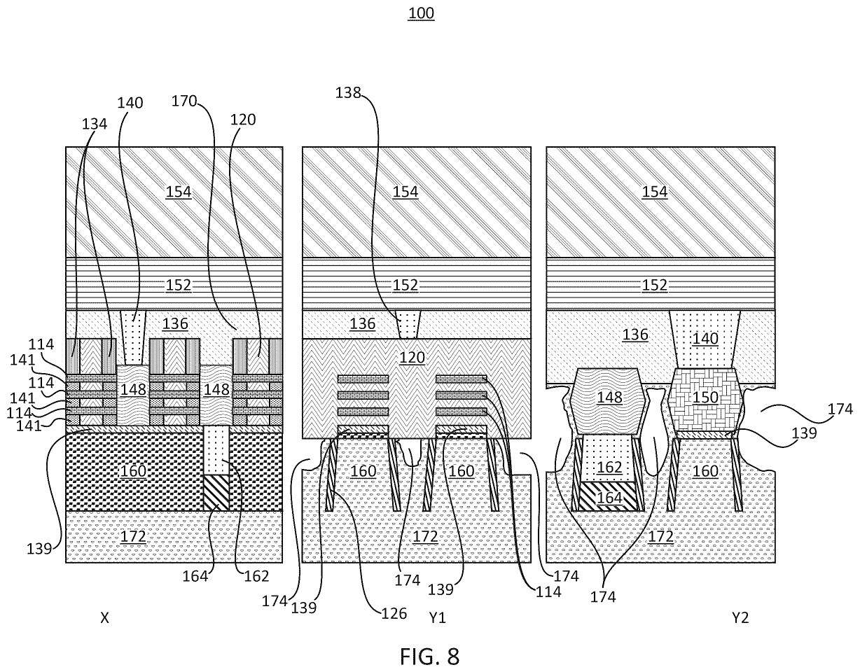

Referring to FIG. 8, beginning with the partial removal of the FILD 136 as depicted in FIG. 6, a non-conformal deposition process can be employed to deposit a single composition dielectric material 172 on surfaces within voids 166 and 168 (depicted in FIG. 6). The single composition dielectric material 172 can be any suitable dielectric material (e.g., a material that can be employed for ILD and STI) with adequate dielectric properties to replace the material of STI 128 and the FILD 136. The non-conformal deposition process can include a physical vapor deposition (PVD) process, although other deposition processes can be employed.

Since the deposition process is performed from the backside of the wafer 100, deposition materials need to pass through the constrictions formed by voids 166. This leads to build up of material within the constricted space of voids 166 which pinches off the deposition materials leading to formation of airgaps 174. Airgaps 174 are formed on sides of the source/drain regions 148 and 150. The airgaps 174 extend from a backside of the wafer 100 to a frontside of the wafer 100.

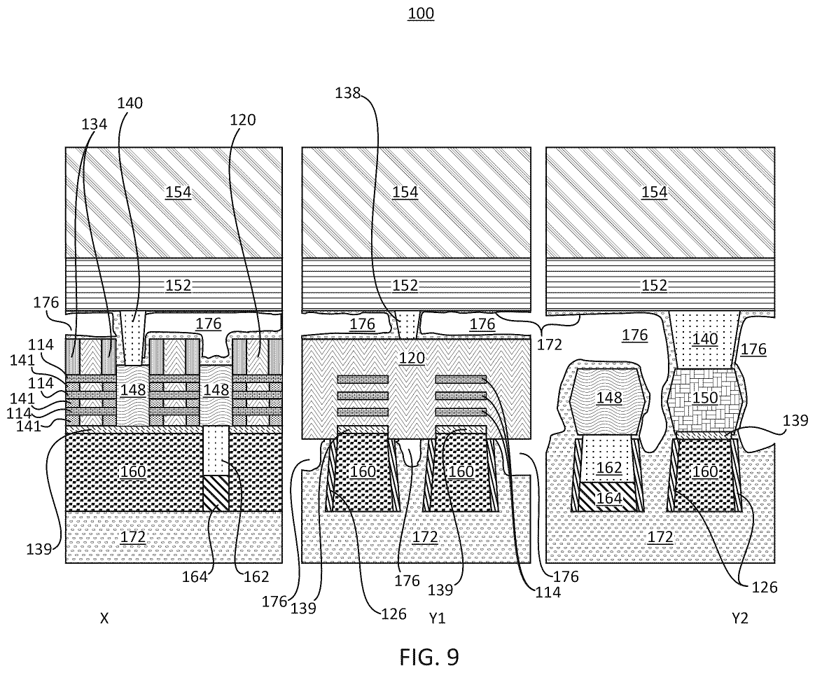

Referring to FIG. 9, beginning with the full removal of the FILD 136 as depicted in FIG. 7, a non-conformal deposition process can be employed to deposit the single composition dielectric material 172 on surfaces within voids 166, 168 and 170 (depicted in FIG. 7). The single composition dielectric material 172 can be any suitable dielectric material (e.g., a material that can be employed for ILD and STI) with adequate dielectric properties to replace the material of STI 128 and the FILD 136. The non-conformal deposition process can include PVD process, although other deposition processes can be employed.

Since the deposition process is performed from the backside of the wafer 100, deposition materials need to pass through the constrictions formed by voids 166. This leads to build up of material within the constricted space of voids 166 which pinches off the deposition materials leading to formation of airgaps 176. Airgaps 176 can be formed on both top and bottom sides of the source/drain regions 148 and 150. For example, the airgaps 176 can extend from a backside of the wafer 100 to a frontside of the wafer 100. In this embodiment, the airgaps 176 extend to and surround the MOL contacts 138, 140. This directly addresses capacitance issues and reduces capacitance (crosstalk) between the gate conductor 120 and the MOL contacts 140.

The airgaps 176 further provide a reduction in capacitance between other conductors in the FEOL region as well, for example, between backside contacts 162 and the MOL contacts 140 and/or between backside contacts 162 and gate conductor 120.

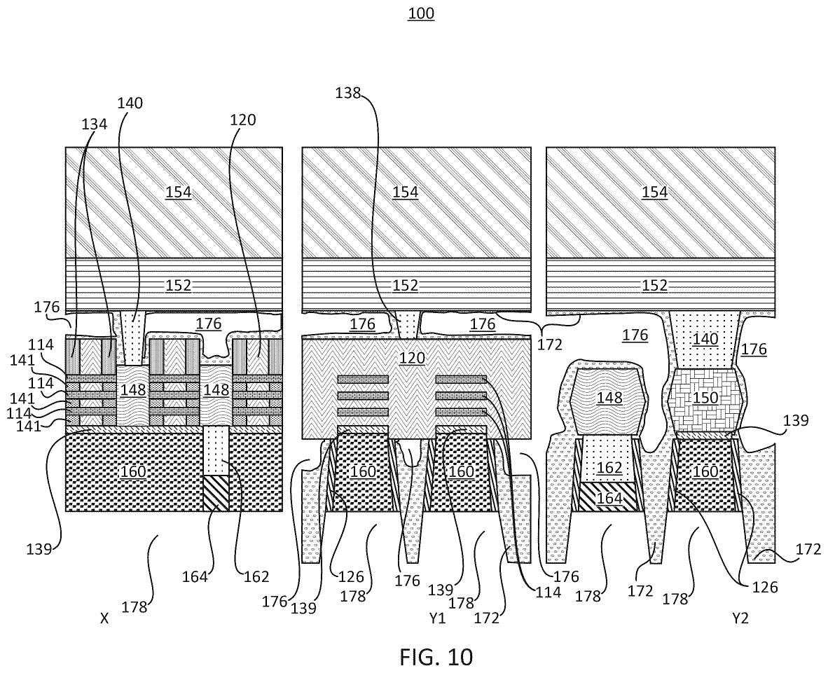

Referring to FIG. 10, the single composition dielectric material 172 is patterned to etch openings 178 for the formation of backside power rails (BSPR). The etch process (e.g., RIE) is selective to the dielectric cap 164 exposes the dielectric cap 164 formed on the backside contacts 162. The dielectric cap 164 is then removed by an additional etch process that exposes the backside contact 162. The dielectric cap 164 is removed selectively to the BILD 160, the single composition dielectric material 172 and dielectric liner 126 and stops on the backside contact 162.

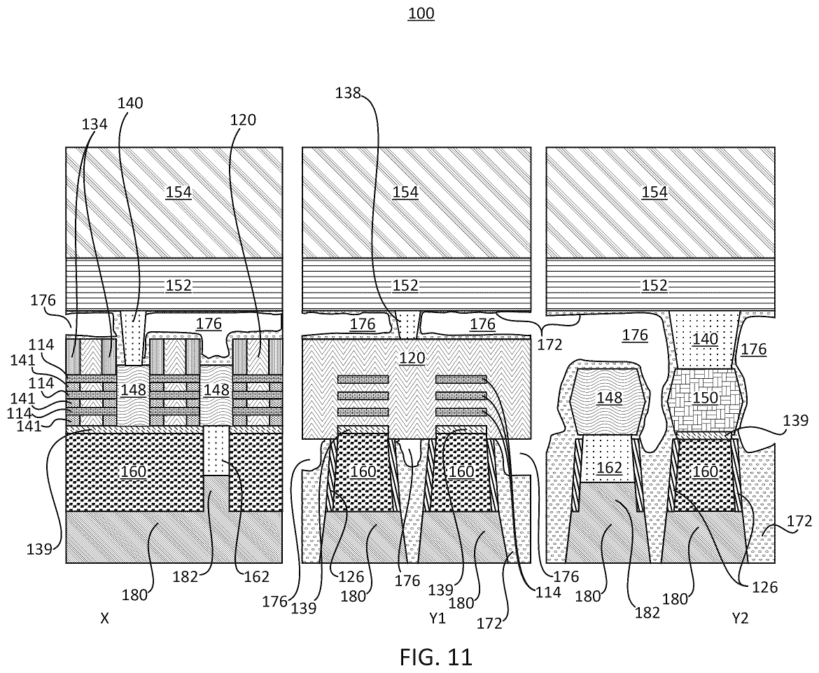

Referring to FIG. 11, the backside power rails 180 are deposited in the openings 178 and fill a region vacated by the dielectric cap 164 to form an extension 182 that connects to and forms a portion of the backside contact 162. The backside power rails 180 can include any suitable conductive materials, e.g., Cu, Ru, etc. The conductive materials are planarized (e.g., by CMP) to remove excess materials from a free surface of the single composition dielectric material 172.

The backside power rails 180 contact the backside contacts 162 to provide supply voltage to logic or memory devices associated with the source/drain regions 148 and 150. The backside power rails 180 can alternate between positive supply voltage (VDD) and negative supply voltage (VSS or ground), although other arrangements are contemplated.

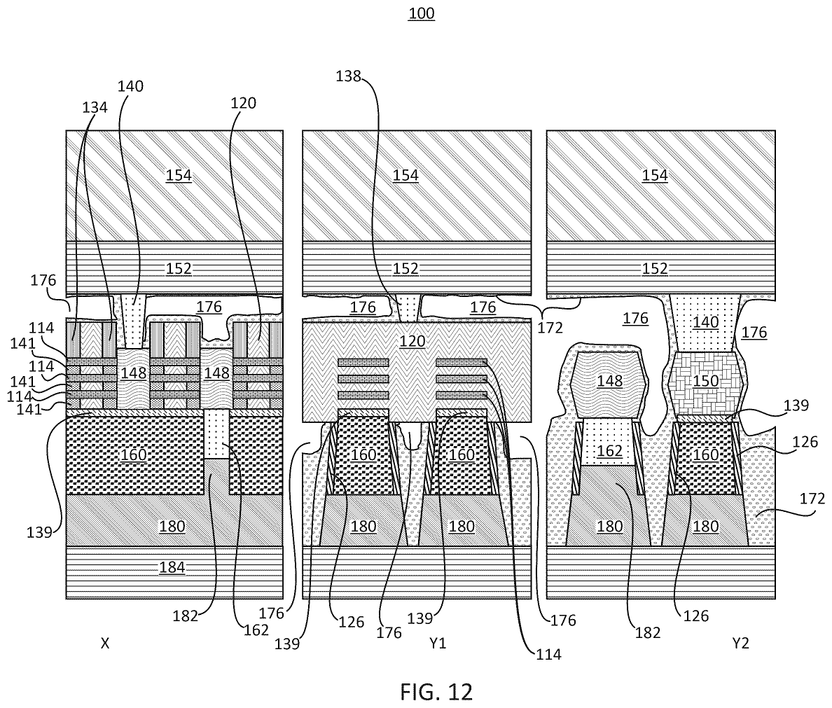

Referring to FIG. 12, a backside interconnect layer 184 is formed, which can include metal structures and dielectric layers to complete the bottom side of the wafer 100 and provide electrical access to the devices formed. The backside interconnect layer 184 is formed on the single composition dielectric material 172 and the backside power rails 180. The backside interconnect layer 184 can include a backside power distribution network (BSPDN) that includes dielectric layers and metallization structures that can connect components on the wafer 100. The BSPDN connects to the backside power rails 180 which, in turn, connect to the backside contacts 162.

The single composition dielectric material 172 provides a single material applied in a single deposition process that can fill regions in a semiconductor device that have be removed with the intention of forming airgaps therein. The single composition dielectric material 172 can replace all or portions of STI 128 and all or portions of the FILD 136. In some embodiments, the single composition dielectric material 172 is disposed between all or some of backside contacts 162, backside power rails 180, (and under) gate conductor 120, between MOL contacts 138, 140, between source/drain regions 148, 150. The single composition dielectric material 172 can line the cavities provided in the STI 128 and/or the FILD 136. In this way, single composition dielectric material 172 and airgaps 176 are employed as dielectric isolation between conductive components to reduce capacitance therebetween.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor—or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product.

The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
front end of line (FEOL) devices arranged in a FEOL layer defining a frontside and a backside opposite the frontside;
a single composition dielectric material covering the FEOL devices and disposed in shallow trench isolation regions between the FEOL devices; and
the single composition dielectric material having voids disposed therein that provide airgaps between the FEOL devices.

2. The semiconductor device as recited in claim 1, wherein the single composition dielectric material fills the shallow trench isolation regions and includes a backside airgap within the shallow trench isolation regions.

3. The semiconductor device as recited in claim 2, wherein the backside airgap extends under a gate conductor on the backside.

4. The semiconductor device as recited in claim 2, wherein the backside airgap extends between backside contacts.

5. The semiconductor device as recited in claim 1, wherein the single composition dielectric material lines a region of a frontside interlayer dielectric and includes a frontside airgap within a region of the frontside interlayer dielectric.

6. The semiconductor device as recited in claim 5, wherein the frontside airgap is disposed between middle of the line contacts.

7. The semiconductor device as recited in claim 5, wherein the frontside airgap is disposed between source/drain regions of the FEOL devices.

8. The semiconductor device as recited in claim 1, further comprising backside power rails to connect to the FEOL devices by backside contacts.

9. The semiconductor device as recited in claim 8, wherein the backside power rails include an extension that forms a portion of the backside contacts.

10. A semiconductor device, comprising:
front end of line (FEOL) devices arranged in a FEOL layer defining a frontside and a backside opposite the frontside;
a single composition dielectric material covering the FEOL devices and disposed in shallow trench isolation regions between the FEOL devices; and
the single composition dielectric having an airgap that extends from within the shallow trench isolation regions to a region of a frontside interlayer dielectric between the FEOL devices.

11. The semiconductor device as recited in claim 10, wherein the airgap extends under a gate conductor on the backside.

12. The semiconductor device as recited in claim 10, wherein the airgap extends between backside contacts.

13. The semiconductor device as recited in claim 10, wherein the airgap is disposed between middle of the line contacts.

14. The semiconductor device as recited in claim 10, wherein the airgap is disposed between source/drain regions of the FEOL devices.

15. The semiconductor device as recited in claim 10, further comprising backside power rails to connect to the FEOL devices by backside contacts.

16. The semiconductor device as recited in claim 15, wherein the backside power rails include an extension that forms a portion of the backside contacts.

17. A semiconductor device, comprising:
front end of line (FEOL) devices arranged in a FEOL layer defining a frontside and a backside opposite the frontside;
a single composition dielectric material covering the FEOL devices and disposed in shallow trench isolation regions between the FEOL devices;
the single composition dielectric having an airgap that extends from within the shallow trench isolation regions to a region of a frontside interlayer dielectric between the FEOL devices; and
the single composition dielectric includes in a backside interlayer dielectric and is disposed between backside contacts and buried power rails.

18. The semiconductor device as recited in claim 17, wherein the airgap extends under a gate conductor and between the backside contacts on the backside.

19. The semiconductor device as recited in claim 17, wherein the airgap is disposed between middle of the line contacts and between source/drain regions of the FEOL devices.

20. The semiconductor device as recited in claim 17, wherein the backside power rails include an extension that forms a portion of the backside contacts.
